(19) United States
(12) Patent Application Publication
(10) Pub. No.: US 2019/0353434 A1
(43) Pub. Date: Nov. 21, 2019

(54) COOLING APPARATUS

(71) Applicant: HONDA MOTOR CO., LTD., Tokyo (JP)

(72) Inventors: Masayuki Arai, Wako-shi (JP); Takahiro Uneme, Wako-shi (JP)

(21) Appl. No.: 16/411,234

(22) Filed: May 14, 2019

(30) Foreign Application Priority Data
May 16, 2018 (JP) 2018-094589

(51) Int. Cl. F28F 13/12; H01L 23/473; H05K 7/20

(52) U.S. Cl. CPC F28F 13/12; H05K 7/20927; H05K 7/20872; H01L 23/473

(57) ABSTRACT

A cooling apparatus is a cooling apparatus in which a refrigerant flows in a refrigerant flow passage and thereby cools a cooled body that is mounted on a mount part, the cooling apparatus including a heat release part that is arranged in the refrigerant flow passage, wherein the heat release part includes a plurality of first surfaces that are formed so as to approach the mount part side as proceeding in a first direction along a flow direction of the refrigerant flow passage and a plurality of second surfaces that are formed so as to be separated from the mount part as proceeding in the first direction, and the plurality of first surfaces and the plurality of second surfaces are alternately arranged in the first direction.

### CROSS-REFERENCE TO RELATED APPLICATION

Priority is claimed on Japanese Patent Application No. 2018-094589, filed on May 16, 2018, the contents of which are incorporated herein by reference.

### BACKGROUND

### Field of the Invention

The present invention relates to a cooling apparatus.

### Background

In the related art, a semiconductor device is known which includes a cooling apparatus in which a shape of a connection part or the like of an introduction port and an exhaust port of a coolant is improved, and a pressure loss at the connection part or the like is reduced (for example, refer to Japanese Unexamined Patent Application, First Publication No. 2015-079819). The cooling apparatus of the semiconductor device includes an introduction port and an exhaust port that are provided at a diagonal position on each of side walls that face each other of a case, an introduction passage that is connected to the introduction port and that is formed in the case, an exhaust passage that is connected to the exhaust port and that is formed in the case, and a cooling flow passage between the introduction passage and the exhaust passage.

### SUMMARY

In the cooling apparatus of the semiconductor device disclosed in Japanese Unexamined Patent Application, First Publication No. 2015-079819, a flow of a refrigerant that approaches a semiconductor element (cooled body) side and a flow of the refrigerant that leaves the semiconductor element (cooled body) are not formed in the cooling flow passage. Therefore, according to the cooling apparatus of the semiconductor device disclosed in Japanese Unexamined Patent Application, First Publication No. 2015-079819, there is a possibility that it is impossible to sufficiently improve a cooling efficiency of the semiconductor element (cooled body).

An aspect of the present invention provides a cooling apparatus capable of improving a cooling efficiency of a cooled body.

(1) A cooling apparatus according to an aspect of the present invention is a cooling apparatus in which a refrigerant flows in a refrigerant flow passage and thereby cools a cooled body that is mounted on a mount part, the cooling apparatus including a heat release part that is arranged in the refrigerant flow passage, wherein the heat release part includes a plurality of first surfaces that are formed so as to approach the mount part side as proceeding in a first direction along a flow direction of the refrigerant flow passage and a plurality of second surfaces that are formed so as to be separated from the mount part as proceeding in the first direction, and the plurality of first surfaces and the plurality of second surfaces are alternately arranged in the first direction.

(2) In the above cooling apparatus described in (1), the first surface may include a first part that is formed so as to approach one side in a second direction that is orthogonal to the first direction and that is parallel to the mount part as proceeding in the first direction, and the second surface may include a second part that is formed so as to approach another side in the second direction as proceeding in the first direction.

(3) In the above cooling apparatus described in (2), the first surface and the second surface may be formed to be displaced from each other in the second direction when seen in the first direction.

(4) In the above cooling apparatus described in any one of (1) to (3), the plurality of first surfaces may be formed to be overlapped with one another when seen in the first direction, and the plurality of second surfaces may be formed to be overlapped with one another when seen in the first direction.

(5) In the above cooling apparatus described in (2), the heat release part may include at least a first fin that extends in the first direction and a second fin that is arranged adjacent to the first fin in the second direction and that extends in the first direction, each of the first fin and the second fin may include the first surface having the first part and the second surface having the second part, one of the first fin and the second fin may form a refrigerant flow that swirls clockwise as proceeding in the first direction when seen in the first direction, and the other of the first fin and the second fin may form a refrigerant flow that swirls counterclockwise as proceeding in the first direction when seen in the first direction.

(6) In the above cooling apparatus described in (5), when seen in the first direction, the first surface of the first fin and the first surface of the second fin may be overlapped with each other, or the second surface of the first fin and the second surface of the second fin may be overlapped with each other.

(7) In the above cooling apparatus described in (2), the cooled body may be arranged at a position where the first surface is arranged in the second direction.

In the above cooling apparatus described in (1), the heat release part that is arranged in the refrigerant flow passage includes the plurality of first surfaces that are formed so as to approach the cooled body side as proceeding in the first direction along the flow direction of the refrigerant flow passage and the plurality of second surfaces that are formed so as to be separated from the cooled body as proceeding in the first direction.

Therefore, in the above cooling apparatus described in (1), the first surface is able to form a refrigerant flow that approaches the cooled body side, and the second surface is able to form a refrigerant flow that is separated from the cooled body. As a result, it is possible to reduce a refrigerant flow that passes through the refrigerant flow passage without cooling the cooled body and improve a cooling efficiency of the cooled body compared to a case where the refrigerant flow that approaches the cooled body side and the refrigerant flow that is separated from the cooled body are not formed.

In the above cooling apparatus described in (2), the first surface may include the first part described above, and the second surface may include the second part described above.

When being formed in that way, the first part is able to form a refrigerant flow that approaches one side in the second direction that is orthogonal to the first direction and that is parallel to the mount part, and the second part is able to form a refrigerant flow that approaches another side in the second direction. As a result, it is possible to reduce a refrigerant flow that passes through the refrigerant flow passage without cooling the cooled body and improve a cooling efficiency of the cooled body compared to a case where the refrigerant flow that approaches the one side in the second direction and the refrigerant flow that approaches the other side in the second direction are not formed.

In the above cooling apparatus described in (3), the first surface and the second surface may be formed to be displaced from each other in the second direction when seen in the first direction.

When being formed in that way, it is possible to reduce a possibility that the refrigerant flow which is formed by the first surface and which approaches the cooled body side and the refrigerant flow which is formed by the second surface and which is separated from the cooled body collide with each other.

In the above cooling apparatus described in (4), the plurality of first surfaces may be formed to be overlapped with one another when seen in the first direction.

When being formed in that way, it is possible to collectively strengthen the refrigerant flow that approaches the cooled body side compared to a case where the plurality of first surfaces are not formed to be overlapped with one another when seen in the first direction. As a result, it is possible to reduce a refrigerant flow that passes through the refrigerant flow passage without cooling the cooled body and improve a cooling efficiency of the cooled body.

In the above cooling apparatus described in (4), the plurality of second surfaces may be formed to be overlapped with one another when seen in the first direction.

When being formed in that way, it is possible to collectively strengthen the refrigerant flow that is separated from the cooled body compared to a case where the plurality of second surfaces are not formed to be overlapped with one another when seen in the first direction. As a result, it is possible to reduce a refrigerant flow that passes through the refrigerant flow passage without cooling the cooled body and improve a cooling efficiency of the cooled body.

In the above cooling apparatus described in (5), one of the first fin and the second fin of the heat release part which forms the refrigerant flow that swirls clockwise as proceeding in the first direction when seen in the first direction and the other of the first fin and the second fin of the heat release part which forms the refrigerant flow that swirls counterclockwise as proceeding in the first direction when seen in the first direction may be arranged adjacent to each other in the second direction.

When being formed in that way, compared to a case where the heat release part does not include the first fin and the second fin, it is possible to strengthen the refrigerant flow that crosses with the first direction, and it is possible to improve a cooling efficiency of the cooled body.

In the above cooling apparatus described in (6), when seen in the first direction, the first surface of the first fin and the first surface of the second fin may be overlapped with each other.

When being formed in that way, compared to a case where the first surface of the first fin and the first surface of the second fin are not overlapped with each other when seen in the first direction, it is possible to strengthen the refrigerant flow that approaches the cooled body side, and it is possible to improve a cooling efficiency of the cooled body.

In the above cooling apparatus described in (6), when seen in the first direction, the second surface of the first fin and the second surface of the second fin may be overlapped with each other.

When being formed in that way, compared to a case where the second surface of the first fin and the second surface of the second fin are not overlapped with each other when seen in the first direction, it is possible to strengthen the refrigerant flow that is separated from the cooled body, and it is possible to improve a cooling efficiency of the cooled body.

In the above cooling apparatus described in (7), the cooled body may be arranged at the position where the first surface is arranged in the second direction.

When being formed in that way, by allowing the refrigerant flow to hit the mount part at a position where the cooled body is mounted, it is possible to improve a cooling efficiency of the cooled body compared to a case where the cooled body is arranged at a position where the first surface is not arranged in the second direction.

### BRIEF DESCRIPTION OF THE DRAWINGS

FIG. 1A is a view showing an example of a cooling apparatus of a first embodiment.

FIG. 1B is a view showing an example of the cooling apparatus of the first embodiment.

FIG. 2 is a cross-sectional view of a cooling part along an A-A line in FIG. 1B.

FIG. 3A is a view describing a change of a cross-sectional shape of a fin.

FIG. 3B is a view describing the change of the cross-sectional shape of the fin.

FIG. 3C is a view describing the change of the cross-sectional shape of the fin.

FIG. 3D is a view describing the change of the cross-sectional shape of the fin.

FIG. 3E is a view describing the change of the cross-sectional shape of the fin.

FIG. 3F is a view describing the change of the cross-sectional shape of the fin.

FIG. 4 is a partial cross-sectional view of the cooling part along an A1-A1 line in FIG. 1B.

FIG. 5A is a view showing an example of a cooling apparatus of a second embodiment.

FIG. 5B is a view showing an example of the cooling apparatus of the second embodiment.

FIG. 6 is a cross-sectional view of a cooling part along a Q-Q line in FIG. 5B.

FIG. 7A is a view showing an example of a cooling apparatus of a third embodiment.

FIG. 7B is a view showing an example of the cooling apparatus of the third embodiment.

FIG. 8 is a partial cross-sectional view of the cooling part along a R-R line in FIG. 7B.

FIG. 9 is a perspective view of a fin of the cooling apparatus of the third embodiment.

FIG. 10A is a view showing an example of a cooling apparatus of a fourth embodiment.

FIG. 10B is a view showing an example of the cooling apparatus of the fourth embodiment.

FIG. 11 is a view showing an example of a part of a vehicle to which the cooling apparatuses of the first to fifth embodiments are applicable.

### DESCRIPTION OF THE EMBODIMENTS

Hereinafter, embodiments of a cooling apparatus of the present invention are described with reference to the drawings.

### First Embodiment

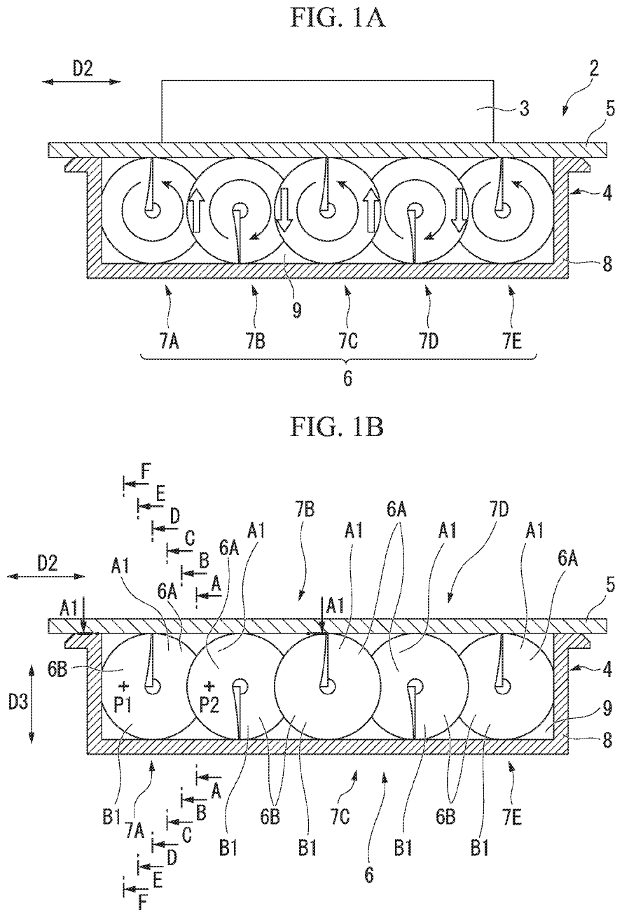

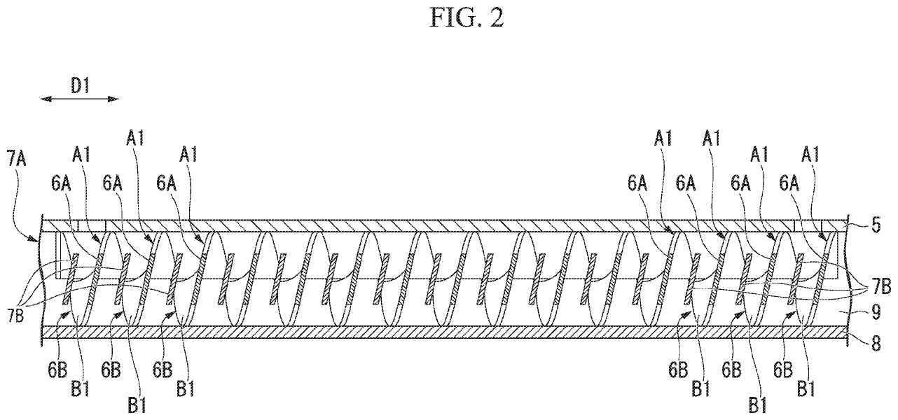

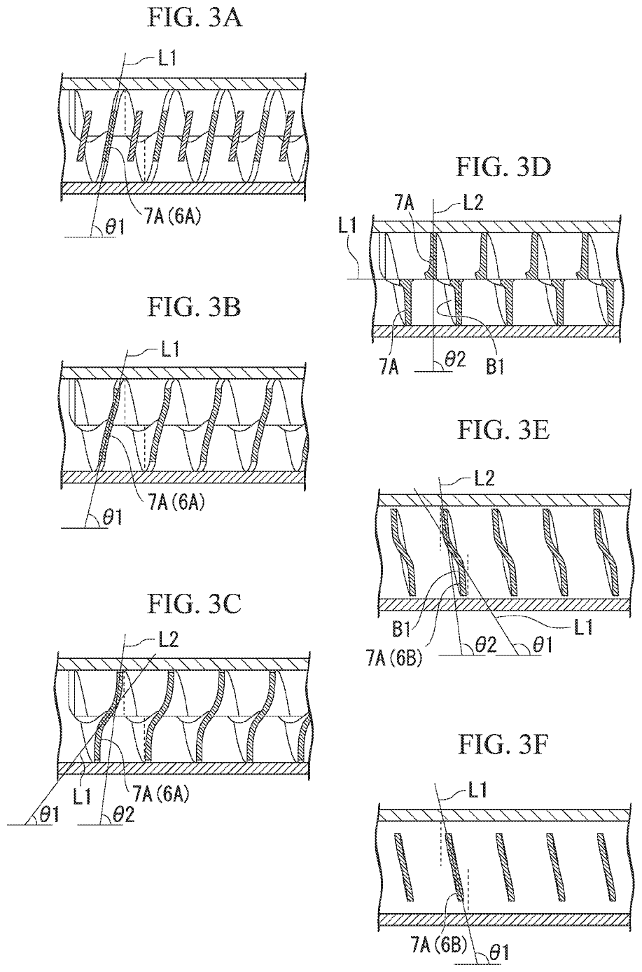

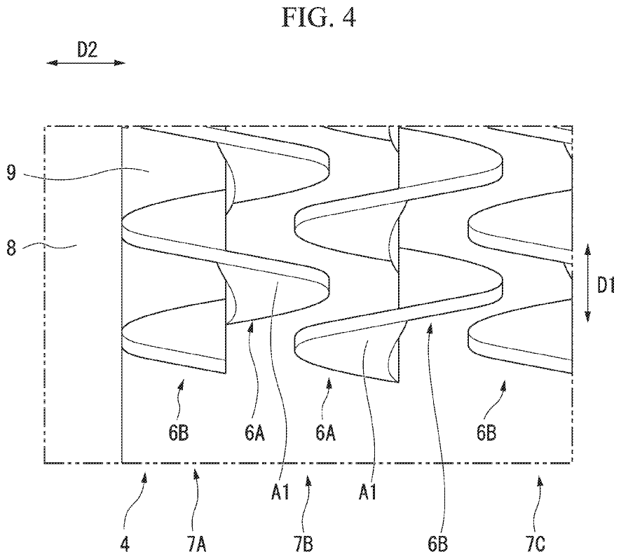

FIG. 1A and FIG. 1B are views showing an example of a cooling apparatus 2 of a first embodiment. In detail, FIG. 1A is a view showing a relationship between a cooled body 3 and an internal structure of a cooling part 4 and the like of the cooling apparatus 2 of the first embodiment. FIG. 1B is a view extracting and showing only the cooling part 4 in FIG. 1A. FIG. 2 is a cross-sectional view of the cooling part 4 along an A-A line in FIG. 1B. FIGS. 3A to 3F are views describing a change of a cross-sectional shape of a fin 7A. In detail, FIG. 3A is a cross-sectional view of the fin 7A and the like along the A-A line in FIG. 1B. FIG. 3B is a cross-sectional view of the fin 7A and the like along the B-B line in FIG. 1B. FIG. 3C is a cross-sectional view of the fin 7A and the like along the C-C line in FIG. 1B. FIG. 3D is a cross-sectional view of the fin 7A and the like along the D-D line in FIG. 1B. FIG. 3E is a cross-sectional view of the fin 7A and the like along the E-E line in FIG. 1B. FIG. 3F is a cross-sectional view of the fin 7A and the like along the F-F line in FIG. 1B. FIG. 4 is a partial cross-sectional view of the cooling part 4 along the A1-A1 line in FIG. 1B.

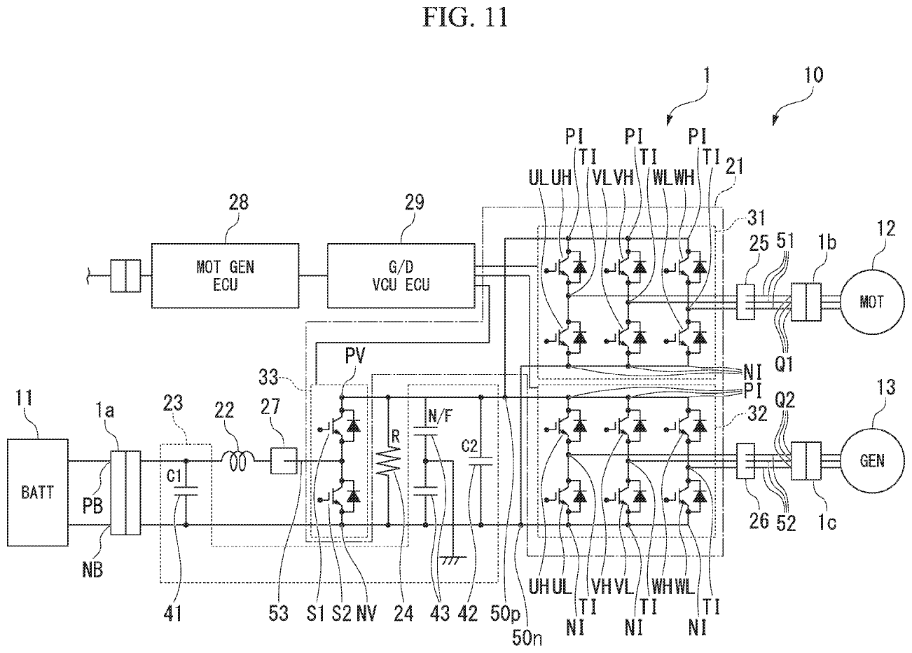

In the example shown in FIG. 1A to FIG. 4, the cooling apparatus 2 includes the cooled body 3 and the cooling part 4 that cools the cooled body 3. The cooled body 3 is a known arbitrary object that requires cooling and is, for example, a heat generator. The heat generator includes, for example, a power module (power semiconductor module) 21 (refer to FIG. 11) and the like having switching elements UH, UL, VH, VL, WH, WL, S1, S2 (refer to FIG. 11).

The cooling part 4 includes a mount part 5, a heat release part 6, and a case part 8. The cooled body 3 is mounted on one surface (an upper surface in FIG. 1A) of the mount part 5. The refrigerant flow passage 9 is defined by another surface (a lower surface in FIG. 1A) of the mount part 5 and an inner surface of the case part 8.

The heat release part 6 is thermally connected to the cooled body 3 via the mount part 5. The heat release part 6 is arranged in the refrigerant flow passage 9. The refrigerant flows in the refrigerant flow passage 9.

A first direction D1 (right-to-left direction in FIG. 2, right-to-left direction in FIGS. 3A to 3F, vertical direction in FIG. 4) is directed along a main flow direction (right-to-left direction in FIG. 2, right-to-left direction in FIGS. 3A to 3F, vertical direction in FIG. 4) of the refrigerant in the refrigerant flow passage 9. That is, in the example shown in FIG. 1A to FIG. 4, the refrigerant mainly proceeds (flows) in the refrigerant flow passage 9 to one side (rightward direction in FIG. 2, rightward direction in FIGS. 3A to 3F, upward direction in FIG. 4) in the first direction D1.

The refrigerant that flows in the refrigerant flow passage 9 cools the heat release part 6, and accordingly, the cooled body 3 that is thermally connected to the heat release part 6 is cooled.

If the refrigerant that flows in the refrigerant flow passage 9 passes by the inside of the refrigerant flow passage 9 without cooling the heat release part 6, there is a possibility that it is impossible to sufficiently cool the cooled body 3.

From this viewpoint, the cooling apparatus 2 of the first embodiment has a configuration as described below.

In the example shown in FIG. 1A to FIG. 4, the heat release part 6 includes, for example, five fins 7A, 7B, 7C, 7D, 7E that extend in the first direction D1 (right-to-left direction in FIG. 2, right-to-left direction in FIGS. 3A to 3F, vertical direction in FIG. 4).

In another example, the heat release part 6 may include only one fin 7A that extends in the first direction D1.

In the example shown in FIG. 1A to FIG. 4, the fin 7A is arranged adjacent to the fin 7B in a second direction D2 (right-to-left direction in FIG. 1A, FIG. 1B, and FIG. 4) that is orthogonal to the first direction D1 and that is parallel to the mount part 5. The fin 7B is arranged adjacent to the fin 7C in the second direction D2.

The fin 7C is arranged adjacent to the fin 7D in the second direction D2. The fin 7D is arranged adjacent to the fin 7E in the second direction D2. A third direction D3 shown in FIG. 1B is a height direction that is orthogonal to the first direction D1 and the second direction D2.

In the example shown in FIG. 1A to FIG. 4, the fins 7A, 7B, 7C, 7D, 7E are formed in a spiral shape (in detail, a shape of a known auger screw having no central axis part). As described later, the fins 7A, 7B, 7C, 7D, 7E having the spiral shape actively guide (move) a refrigerant flow in the vertical direction (height direction D3) in FIG. 1B, FIG. 2, and FIGS. 3A to 3F.

In another example, the fins 7A, 7B, 7C, 7D, 7E may be formed in a shape other than the spiral shape.

In the example shown in FIG. 1A to FIG. 4, for example, the refrigerant that proceeds at a position P1 in FIG. 1B in the first direction D1 (rightward direction in FIG. 2, rightward direction in FIGS. 3A to 3F, upward direction in FIG. 4) first hits a left surface 6B of the fin 7A.

As shown in FIG. 1B, FIG. 2, FIG. 3D, FIG. 3E, and FIG. 4, the left surface 6B of the fin 7A is tilted such that a lower part B1 (lower part in FIG. 3D and FIG. 3E) of the left surface 6B is positioned at a further back side (rightward in FIG. 2, rightward in FIG. 3D and FIG. 3E, upward in FIG. 4) than an upper part (upper part in FIG. 1B, FIG. 2, FIG. 3D, and FIG. 3E) of the left surface 6B.

Therefore, the refrigerant flow after hitting the left surface 6B of the fin 7A becomes a flow (refer to an arrow on the fin 7A in FIG. 1A) that swirls counterclockwise around a central axis line of the fin 7A from the position P1 in FIG. 1B when seen in the first direction D1 (that is, in FIG. 1B).

The refrigerant which hits the left surface 6B of the fin 7A and of which the flow direction is changed next flows along the lower part B1 of the left surface 6B of the fin 7A.

As shown in FIG. 1B, FIG. 2, and FIG. 4, the lower part B1 of the left surface 6B of the fin 7A is tilted such that a right portion (right portion in FIG. 1B and FIG. 4) of the lower part B1 is positioned at a further back side (rightward in FIG. 2, upward in FIG. 4) than a left portion (left portion in FIG. 1B and FIG. 4) of the lower part B1.

Therefore, the refrigerant flow along the lower part B1 of the left surface 6B of the fin 7A becomes a flow (refer to the arrow on the fin 7A in FIG. 1A) that swirls counterclockwise around the central axis line of the fin 7A as proceeding in the first direction D1 (rightward direction in FIG. 2, upward direction in FIG. 4) when seen in the first direction D1 (that is, in FIG. 1B).

The refrigerant that flows along the lower part B1 of the left surface 6B of the fin 7A next flows along a right surface 6A of the fin 7A.

As shown in FIG. 1B, FIG. 2, FIG. 3A, FIG. 3B, FIG. 3C, and FIG. 4, the right surface 6A of the fin 7A is tilted such that an upper part A1 (upper part in FIG. 3A to FIG. 3C) of the right surface 6A is positioned at a further back side (rightward in FIG. 2, rightward in FIG. 3A to FIG. 3C, upward in FIG. 4) than a lower part (lower part in FIG. 1B, FIG. 2, and FIG. 3A to FIG. 3C) of the right surface 6A.

Therefore, the refrigerant flow along the right surface 6A of the fin 7A becomes a flow (refer to the arrow on the fin 7A in FIG. 1A) that swirls counterclockwise around the central axis line of the fin 7A as proceeding in the first direction D1 (rightward direction in FIG. 2, upward direction in FIG. 4) when seen in the first direction D1 (that is, in FIG. 1B).

The refrigerant that flows along the lower part (lower part in FIG. 1B and FIG. 2) of the right surface 6A of the fin 7A next flows along an upper part A1 of the right surface 6A of the fin 7A.

As shown in FIG. 1B, FIG. 2, and FIG. 4, the upper part A1 of the right surface 6A of the fin 7A is tilted such that a left part (left part in FIG. 1B and FIG. 4) of the upper part A1 is positioned at a further back side (rightward in FIG. 2, upward in FIG. 4) than a right part (right part in FIG. 1B and FIG. 4) of the upper part A1.

Therefore, the refrigerant flow along the upper part A1 of the right surface 6A of the fin 7A becomes a flow (refer to the arrow on the fin 7A in FIG. 1A) that swirls counterclockwise around the central axis line of the fin 7A as proceeding in the first direction D1 (rightward direction in FIG. 2, upward direction in FIG. 4) when seen in the first direction D1 (that is, in FIG. 1B).

The refrigerant that flows along the upper part A1 of the right surface 6A of the fin 7A next flows along a left surface 6B (in detail, a second left surface 6B of the fin 7A from the left side in FIG. 2) of the fin 7A.

As described above, the left surface 6B of the fin 7A is tilted such that the lower part B1 of the left surface 6B is positioned at a further back side (rightward in FIG. 2, upward in FIG. 4) than an upper part (upper part in FIG. 1B and FIG. 2) of the left surface 6B.

Therefore, the refrigerant flow along the left surface 6B of the fin 7A becomes a flow that swirls counterclockwise around the central axis line of the fin 7A as proceeding in the first direction D1 when seen in the first direction D1 (that is, in FIG. 1B).

In this way, the refrigerant that proceeds in the refrigerant flow passage 9 in the first direction D1 (rightward direction in FIG. 2, rightward direction in FIGS. 3A to 3F, upward direction in FIG. 4) and that hits the left surface 6B or the right surface 6A of the fin 7A proceeds (flows) in the first direction D1 (rightward direction in FIG. 2, rightward direction in FIGS. 3A to 3F, upward direction in FIG. 4) while swirling counterclockwise around the central axis line of the fin 7A when seen in the first direction D1 (that is, in FIG. 1B).

In the example shown in FIG. 1A to FIG. 4, for example, the refrigerant that proceeds at a position P2 in FIG. 1B in the first direction D1 (rightward direction in FIG. 2, upward direction in FIG. 4) first hits a left surface 6A of the fin 7B.

As shown in FIG. 1B, FIG. 2, and FIG. 4, the left surface 6A of the fin 7B is tilted such that an upper part A1 of the left surface 6A is positioned at a further back side (rightward in FIG. 2, upward in FIG. 4) than a lower part (lower part in FIG. 1B and FIG. 2) of the left surface 6A.

Therefore, the refrigerant flow after hitting the left surface 6A of the fin 7B becomes a flow (refer to an arrow on the fin 7B in FIG. 1A) that swirls clockwise around a central axis line of the fin 7B from the position P2 in FIG. 1B when seen in the first direction D1 (that is, in FIG. 1B).

The refrigerant which hits the left surface 6A of the fin 7B and of which the flow direction is changed next flows along the upper part A1 of the left surface 6A of the fin 7B.

The upper part A1 of the left surface 6A of the fin 7B is tilted such that a right portion (right portion in FIG. 1B and FIG. 4) of the upper part A1 is positioned at a further back side (rightward in FIG. 2, upward in FIG. 4) than a left portion (left portion in FIG. 1B and FIG. 4) of the upper part A1.

Therefore, the refrigerant flow along the upper part A1 of the left surface 6A of the fin 7B becomes a flow (refer to the arrow on the fin 7B in FIG. 1A) that swirls clockwise around the central axis line of the fin 7B as proceeding in the first direction D1 (rightward direction in FIG. 2, upward direction in FIG. 4) when seen in the first direction D1 (that is, in FIG. 1B).

The refrigerant that flows along the upper part A1 of the left surface 6A of the fin 7B next flows along a right surface 6B of the fin 7B.

The right surface 6B of the fin 7B is tilted such that a lower part B1 of the right surface 6B is positioned at a further back side (rightward in FIG. 2, upward in FIG. 4) than an upper part (upper part in FIG. 1B and FIG. 2) of the right surface 6B.

Therefore, the refrigerant flow along the right surface 6B of the fin 7B becomes a flow (refer to the arrow on the fin 7B in FIG. 1A) that swirls clockwise around the central axis line of the fin 7B as proceeding in the first direction D1 (rightward direction in FIG. 2, upward direction in FIG. 4) when seen in the first direction D1 (that is, in FIG. 1B).

The refrigerant that flows along the upper part (upper part in FIG. 1B and FIG. 2) of the right surface 6B of the fin 7B next flows along a lower part B1 of the right surface 6B of the fin 7B.

The lower part B1 of the right surface 6B of the fin 7B is tilted such that a left part (left part in FIG. 1B and FIG. 4) of the lower part B1 is positioned at a further back side (rightward in FIG. 2, upward in FIG. 4) than a right part (right part in FIG. 1B and FIG. 4) of the lower part B1.

Therefore, the refrigerant flow along the lower part B1 of the right surface 6B of the fin 7B becomes a flow (refer to the arrow on the fin 7B in FIG. 1A) that swirls clockwise around the central axis line of the fin 7B as proceeding in the first direction D1 (rightward direction in FIG. 2, upward direction in FIG. 4) when seen in the first direction D1 (that is, in FIG. 1B).

The refrigerant that flows along the lower part B1 of the right surface 6B of the fin 7B next flows along a left surface 6A (in detail, a second left surface 6A of the fin 7B from the front side in FIG. 1B) of the fin 7B.

As described above, the left surface 6A of the fin 7B is tilted such that the upper part A1 of the left surface 6A is positioned at a further back side (rightward in FIG. 2, upward in FIG. 4) than a lower part (upper part in FIG. 1B and FIG. 2) of the left surface 6A.

Therefore, the refrigerant flow along the left surface 6A of the fin 7B becomes a flow that swirls clockwise around the central axis line of the fin 7B as proceeding in the first direction D1 when seen in the first direction D1 (that is, in FIG. 1B).

In this way, the refrigerant that proceeds in the refrigerant flow passage 9 in the first direction D1 (rightward direction in FIG. 2, upward direction in FIG. 4) and that hits the left surface 6A or the right surface 6B of the fin 7B proceeds (flows) in the first direction D1 (rightward direction in FIG. 2, upward direction in FIG. 4) while swirling clockwise around the central axis line of the fin 7B when seen in the first direction D1 (that is, in FIG. 1B).

In detail, in the example shown in FIG. 1A to FIG. 4, the fin 7B has the same pitch as the fin 7A. The winding direction of the fin 7B having the spiral shape is an opposite direction to the winding direction of the fin 7A having the spiral shape.

In the example shown in FIG. 1A to FIG. 4, the shape of the fin 7C is the same as the shape of the fin 7A. Therefore, the refrigerant that proceeds in the refrigerant flow passage 9 in the first direction D1 (rightward direction in FIG. 2, upward direction in FIG. 4) and that hits the left surface 6B or the right surface 6A of the fin 7C proceeds (flows) in the first direction D1 (rightward direction in FIG. 2, upward direction in FIG. 4) while swirling counterclockwise around a central axis line of the fin 7C when seen in the first direction D1 (that is, in FIG. 1B).

The shape of the fin 7D is the same as the shape of the fin 7B. Therefore, the refrigerant that proceeds in the refrigerant flow passage 9 in the first direction D1 (rightward direction in FIG. 2, upward direction in FIG. 4) and that hits the left surface 6A or the right surface 6B of the fin 7D proceeds (flows) in the first direction D1 (rightward direction in FIG. 2, upward direction in FIG. 4) while swirling clockwise around a central axis line of the fin 7D when seen in the first direction D1 (that is, in FIG. 1B).

The shape of the fin 7E is the same as the shape of the fin 7A. Therefore, the refrigerant that proceeds in the refrigerant flow passage 9 in the first direction D1 (rightward direction in FIG. 2, upward direction in FIG. 4) and that hits the left surface 6B or the right surface 6A of the fin 7E proceeds (flows) in the first direction D1 (rightward direction in FIG. 2, upward direction in FIG. 4) while swirling counterclockwise around a central axis line of the fin 7E when seen in the first direction D1 (that is, in FIG. 1B).

In the example shown in FIG. 2, the fin 7A includes fifteen right surfaces 6A that are formed such that the refrigerant approaches the mount part 5 side (upper side in FIG. 2 and FIG. 3A to FIG. 3C) as proceeding in the first direction D1 (rightward direction in FIG. 2, rightward direction in FIGS. 3A to 3F, upward direction in FIG. 4) along the flow direction of the refrigerant flow passage 9. The fin 7A includes fifteen left surfaces 6B that are formed such that the refrigerant is separated from the mount part 5 (that is, moves downward in FIG. 2, FIG. 3D, and FIG. 3E) as proceeding in the first direction D1 (rightward direction in FIG. 2, rightward direction in FIGS. 3A to 3F, upward direction in FIG. 4).

In another example, the fin 7A may include a plurality of right surfaces 6A and a plurality of left surfaces 6B each of which the number is an arbitrary number other than fifteen.

In the example shown in FIG. 2, the fifteen right surfaces 6A and the fifteen left surfaces 6B of the fin 7A are arranged alternately in the first direction D1 (right-to-left direction in FIG. 2, right-to-left direction in FIGS. 3A to 3F, vertical direction in FIG. 4).

In detail, in the example shown in FIG. 2, a first left surface 6B (refer to FIG. 1B) of the fin 7A is arranged on the leftmost side in FIG. 2, a first right surface 6A (refer to FIG. 1B) of the fin 7A is arranged on the right side of the first left surface 6B, a second left surface 6B of the fin 7A is arranged on the right side of the first right surface 6A, a second right surface 6A of the fin 7A is arranged on the right side of the second left surface 6B, a third left surface 6B of the fin 7A is arranged on the right side of the second right surface 6A, a third right surface 6A of the fin 7A is arranged on the right side of the third left surface 6B, a fourth left surface 6B of the fin 7A is arranged on the right side of the third right surface 6A, and a fourth right surface 6A of the fin 7A is arranged on the right side of the fourth left surface 6B.

A fifteenth right surface 6A of the fin 7A is arranged on the rightmost side in FIG. 2, a fifteenth left surface 6B of the fin 7A is arranged on the left side of the fifteenth right surface 6A, a fourteenth right surface 6A of the fin 7A is arranged on the left side of the fifteenth left surface 6B, a fourteenth left surface 6B of the fin 7A is arranged on the left side of the fourteenth right surface 6A, a thirteenth right surface 6A of the fin 7A is arranged on the left side of the fourteenth left surface 6B, a thirteenth left surface 6B of the fin 7A is arranged on the left side of the thirteenth right surface 6A, a twelfth right surface 6A of the fin 7A is arranged on the left side of the thirteenth left surface 6B, and a twelfth left surface 6B of the fin 7A is arranged on the left side of the twelfth right surface 6A.

Therefore, the fin 7A is able to form, by the right surface 6A, a refrigerant flow that approaches the mount part 5 side (upper side in FIG. 2 and FIGS. 3A to 3F) and to form, by the left surface 6B, a refrigerant flow that is separated from the mount part 5 (that is, moves downward in FIG. 2 and FIGS. 3A to 3F).

In the example shown in FIG. 1A to FIG. 4, the fin 7B includes fifteen left surfaces 6A that are formed such that the refrigerant approaches the mount part 5 side (upper side in FIG. 1B and FIG. 2) as proceeding in the first direction D1 (rightward direction in FIG. 2, upward direction in FIG. 4). The fin 7B includes fifteen right surfaces 6B that are formed such that the refrigerant is separated from the mount part 5 (that is, moves downward in FIG. 1B and FIG. 2) as proceeding in the first direction D1 (rightward direction in FIG. 2, upward direction in FIG. 4).

Therefore, the fin 7B is able to form, by the left surface 6A, a refrigerant flow that approaches the mount part 5 side (upper side in FIG. 1B and FIG. 2) and to form, by the right surface 6B, a refrigerant flow that is separated from the mount part 5 (that is, moves downward in FIG. 1B and FIG. 2).

In the example shown in FIG. 1A to FIG. 4, the fin 7C includes fifteen right surfaces 6A that are formed such that the refrigerant approaches the mount part 5 side (upper side in FIG. 1B and FIG. 2) as proceeding in the first direction D1 (rightward direction in FIG. 2, upward direction in FIG. 4). The fin 7C includes fifteen left surfaces 6B that are formed such that the refrigerant is separated from the mount part 5 (that is, moves downward in FIG. 1B and FIG. 2) as proceeding in the first direction D1 (rightward direction in FIG. 2, upward direction in FIG. 4).

Therefore, the fin 7C is able to form, by the right surface 6A, a refrigerant flow that approaches the mount part 5 side (upper side in FIG. 1B and FIG. 2) and to form, by the left surface 6B, a refrigerant flow that is separated from the mount part 5 (that is, moves downward in FIG. 1B and FIG. 2).

In the example shown in FIG. 1A to FIG. 4, the fin 7D includes fifteen left surfaces 6A that are formed such that the refrigerant approaches the mount part 5 side (upper side in FIG. 1B and FIG. 2) as proceeding in the first direction D1 (rightward direction in FIG. 2, upward direction in FIG. 4). The fin 7D includes fifteen right surfaces 6B that are formed such that the refrigerant is separated from the mount part 5 (that is, moves downward in FIG. 1B and FIG. 2) as proceeding in the first direction D1 (rightward direction in FIG. 2, upward direction in FIG. 4).

Therefore, the fin 7D is able to form, by the left surface 6A, a refrigerant flow that approaches the mount part 5 side (upper side in FIG. 1B and FIG. 2) and to form, by the right surface 6B, a refrigerant flow that is separated from the mount part 5 (that is, moves downward in FIG. 1B and FIG. 2).

In the example shown in FIG. 1A to FIG. 4, the fin 7E includes fifteen right surfaces 6A that are formed such that the refrigerant approaches the mount part 5 side (upper side in FIG. 1B and FIG. 2) as proceeding in the first direction D1 (rightward direction in FIG. 2, upward direction in FIG. 4). The fin 7E includes fifteen left surfaces 6B that are formed such that the refrigerant is separated from the mount part 5 (that is, moves downward in FIG. 1B and FIG. 2) as proceeding in the first direction D1 (rightward direction in FIG. 2, upward direction in FIG. 4).

Therefore, the fin 7E is able to form, by the right surface 6A, a refrigerant flow that approaches the mount part 5 side (upper side in FIG. 1B and FIG. 2) and to form, by the left surface 6B, a refrigerant flow that is separated from the mount part 5 (that is, moves downward in FIG. 1B and FIG. 2).

As a result, in the example shown in FIG. 1A to FIG. 4, it is possible to reduce a refrigerant flow that passes through the refrigerant flow passage 9 without cooling the cooled body 3 and improve a cooling efficiency of the cooled body 3 compared to a case where the refrigerant flow that approaches the cooled body 3 side (upper side in FIG. 1A, FIG. 1B, and FIG. 2) and the refrigerant flow that is separated from the cooled body 3 (that is, moves downward in FIG. 1A, FIG. 1B, and FIG. 2) are not formed.

As described above, the right surface 6A of the fin 7A includes the upper part A1 that is formed such that the refrigerant approaches one side (left side in FIG. 1B and FIG. 4) in the second direction D2 as proceeding in the first direction D1 (rightward direction in FIG. 2, upward direction in FIG. 4). Therefore, the fin 7A is able to form, by the upper part A1, a refrigerant flow that approaches the one side (left side in FIG. 1B and FIG. 4) in the second direction D2.

The left surface 6B of the fin 7A includes the lower part B1 that is formed such that the refrigerant approaches another side (right side in FIG. 1B and FIG. 4) in the second direction D2 as proceeding in the first direction D1 (rightward direction in FIG. 2, upward direction in FIG. 4). Therefore, the fin 7A is able to form, by the lower part B1, a refrigerant flow that approaches the other side (right side in FIG. 1B and FIG. 4) in the second direction D2.

As a result, the fin 7A makes it possible to reduce a refrigerant flow that passes through the refrigerant flow passage 9 without cooling the cooled body 3 and improve a cooling efficiency of the cooled body 3 compared to a case where the refrigerant flow that approaches the one side (left side in FIG. 1B and FIG. 4) in the second direction D2 and the refrigerant flow that approaches the other side (right side in FIG. 1B and FIG. 4) in the second direction D2 are not formed.

As described above, the left surface 6A of the fin 7B includes the upper part A1 that is formed such that the refrigerant approaches the other side (right side in FIG. 1B and FIG. 4) in the second direction D2 as proceeding in the first direction D1 (rightward direction in FIG. 2, upward direction in FIG. 4). Therefore, the fin 7B is able to form, by the upper part A1, a refrigerant flow that approaches the other side (right side in FIG. 1B and FIG. 4) in the second direction D2.

The right surface 6B of the fin 7B includes the lower part B1 that is formed such that the refrigerant approaches the one side (left side in FIG. 1B and FIG. 4) in the second direction D2 as proceeding in the first direction D1 (rightward direction in FIG. 2, upward direction in FIG. 4). Therefore, the fin 7B is able to form, by the lower part B1, a refrigerant flow that approaches the one side (left side in FIG. 1B and FIG. 4) in the second direction D2.

As a result, the fin 7B makes it is possible to reduce a refrigerant flow that passes through the refrigerant flow passage 9 without cooling the cooled body 3 and improve a cooling efficiency of the cooled body 3 compared to a case where the refrigerant flow that approaches the other side (right side in FIG. 1B and FIG. 4) in the second direction D2 and the refrigerant flow that approaches the one side (left side in FIG. 1B and FIG. 4) in the second direction D2 are not formed.

As shown in FIG. 1B, the right surface 6A of the fin 7C includes the upper part A1 that is formed such that the refrigerant approaches the one side (left side in FIG. 1B and FIG. 4) in the second direction D2 as proceeding in the first direction D1 (rightward direction in FIG. 2, upward direction in FIG. 4). Therefore, the fin 7C is able to form, by the upper part A1, a refrigerant flow that approaches the one side (left side in FIG. 1B and FIG. 4) in the second direction D2.

The left surface 6B of the fin 7C includes the lower part B1 that is formed such that the refrigerant approaches the other side (right side in FIG. 1B and FIG. 4) in the second direction D2 as proceeding in the first direction D1 (rightward direction in FIG. 2, upward direction in FIG. 4). Therefore, the fin 7C is able to form, by the lower part B1, a refrigerant flow that approaches the other side (right side in FIG. 1B and FIG. 4) in the second direction D2.

As a result, the fin 7C makes it possible to reduce a refrigerant flow that passes through the refrigerant flow passage 9 without cooling the cooled body 3 and improve a cooling efficiency of the cooled body 3 compared to a case where the refrigerant flow that approaches the one side (left side in FIG. 1B and FIG. 4) in the second direction D2 and the refrigerant flow that approaches the other side (right side in FIG. 1B and FIG. 4) in the second direction D2 are not formed.

As shown in FIG. 1B, the left surface 6A of the fin 7D includes the upper part A1 that is formed such that the refrigerant approaches the other side (right side in FIG. 1B) in the second direction D2 as proceeding in the first direction D1 (rightward direction in FIG. 2). Therefore, the fin 7D is able to form, by the upper part A1, a refrigerant flow that approaches the other side (right side in FIG. 1B) in the second direction D2.

The right surface 6B of the fin 7D includes the lower part B1 that is formed such that the refrigerant approaches the one side (left side in FIG. 1B) in the second direction D2 as proceeding in the first direction D1 (rightward direction in FIG. 2). Therefore, the fin 7D is able to form, by the lower part B1, a refrigerant flow that approaches the one side (left side in FIG. 1B) in the second direction D2.

As a result, the fin 7D makes it possible to reduce a refrigerant flow that passes through the refrigerant flow passage 9 without cooling the cooled body 3 and improve a cooling efficiency of the cooled body 3 compared to a case where the refrigerant flow that approaches the other side (right side in FIG. 1B) in the second direction D2 and the refrigerant flow that approaches the one side (left side in FIG. 1B) in the second direction D2 are not formed.

As shown in FIG. 1B, the right surface 6A of the fin 7E includes the upper part A1 that is formed such that the refrigerant approaches the one side (left side in FIG. 1B) in the second direction D2 as proceeding in the first direction D1 (rightward direction in FIG. 2). Therefore, the fin 7E is able to form, by the upper part A1, a refrigerant flow that approaches the one side (left side in FIG. 1B) in the second direction D2.

The left surface 6B of the fin 7E includes the lower part B1 that is formed such that the refrigerant approaches the other side (right side in FIG. 1B) in the second direction D2 as proceeding in the first direction D1 (rightward direction in FIG. 2). Therefore, the fin 7E is able to form, by the lower part B1, a refrigerant flow that approaches the other side (right side in FIG. 1B) in the second direction D2.

As a result, the fin 7E makes it is possible to reduce a refrigerant flow that passes through the refrigerant flow passage 9 without cooling the cooled body 3 and improve a cooling efficiency of the cooled body 3 compared to a case where the refrigerant flow that approaches the one side (left side in FIG. 1B) in the second direction D2 and the refrigerant flow that approaches the other side (right side in FIG. 1B) in the second direction D2 are not formed.

As shown in FIG. 1B, the right surface 6A and the left surface 6B of the fin 7A are formed so as to be displaced from each other in the second direction D2 (right-to-left direction in FIG. 1B and FIG. 4) when seen in the first direction D1 (that is, in FIG. 1B). In detail, the right surface 6A of the fin 7A is arranged on the right side (right side in FIG. 1B and FIG. 4) of the central axis line of the fin 7A, and the left surface 6B of the fin 7A is arranged on the left side (left side in FIG. 1B and FIG. 4) of the central axis line of the fin 7A.

Therefore, it is possible to reduce a possibility that the refrigerant flow which is formed by the right surface 6A of the fin 7A and which approaches the cooled body 3 side (upper side in FIG. 1B) and the refrigerant flow which is formed by the left surface 6B of the fin 7A and which is separated from the cooled body 3 (downward in FIG. 1B) collide with each other.

As shown in FIG. 1B, the left surface 6A and the right surface 6B of the fin 7B are formed so as to be displaced from each other in the second direction D2 (right-to-left direction in FIG. 1B and FIG. 4) when seen in the first direction D1 (that is, in FIG. 1B). In detail, the left surface 6A of the fin 7B is arranged on the left side (left side in FIG. 1B and FIG. 4) of the central axis line of the fin 7B, and the right surface 6B of the fin 7B is arranged on the right side (right side in FIG. 1B and FIG. 4) of the central axis line of the fin 7B.

Therefore, it is possible to reduce a possibility that the refrigerant flow which is formed by the left surface 6A of the fin 7B and which approaches the cooled body 3 side (upper side in FIG. 1B) and the refrigerant flow which is formed by the right surface 6B of the fin 7B and which is separated from the cooled body 3 (downward in FIG. 1B) collide with each other.

As shown in FIG. 1B, the right surface 6A and the left surface 6B of the fin 7C are formed so as to be displaced from each other in the second direction D2 (right-to-left direction in FIG. 1B) when seen in the first direction D1 (that is, in FIG. 1B). In detail, the right surface 6A of the fin 7C is arranged on the right side (right side in FIG. 1B) of the central axis line of the fin 7C, and the left surface 6B of the fin 7C is arranged on the left side (left side in FIG. 1B) of the central axis line of the fin 7C.

Therefore, it is possible to reduce a possibility that the refrigerant flow which is formed by the right surface 6A of the fin 7C and which approaches the cooled body 3 side (upper side in FIG. 1B) and the refrigerant flow which is formed by the left surface 6B of the fin 7C and which is separated from the cooled body 3 (downward in FIG. 1B) collide with each other.

As shown in FIG. 1B, the left surface 6A and the right surface 6B of the fin 7D are formed so as to be displaced from each other in the second direction D2 (right-to-left direction in FIG. 1B) when seen in the first direction D1 (that is, in FIG. 1B). In detail, the left surface 6A of the fin 7D is arranged on the left side (left side in FIG. 1B) of the central axis line of the fin 7D, and the right surface 6B of the fin 7D is arranged on the right side (right side in FIG. 1B) of the central axis line of the fin 7D.

Therefore, it is possible to reduce a possibility that the refrigerant flow which is formed by the left surface 6A of the fin 7D and which approaches the cooled body 3 side (upper side in FIG. 1B) and the refrigerant flow which is formed by the right surface 6B of the fin 7D and which is separated from the cooled body 3 (downward in FIG. 1B) collide with each other.

As shown in FIG. 1B, the right surface 6A and the left surface 6B of the fin 7E are formed so as to be displaced from each other in the second direction D2 (right-to-left direction in FIG. 1B) when seen in the first direction D1 (that is, in FIG. 1B). In detail, the right surface 6A of the fin 7E is arranged on the right side (right side in FIG. 1B) of the central axis line of the fin 7E, and the left surface 6B of the fin 7E is arranged on the left side (left side in FIG. 1B) of the central axis line of the fin 7E.

Therefore, it is possible to reduce a possibility that the refrigerant flow which is formed by the right surface 6A of the fin 7E and which approaches the cooled body 3 side (upper side in FIG. 1B) and the refrigerant flow which is formed by the left surface 6B of the fin 7E and which is separated from the cooled body 3 (downward in FIG. 1B) collide with each other.

As shown in FIG. 1B and FIG. 2, the fifteen right surfaces 6A of the fin 7A are formed to be overlapped with one another when seen in the first direction D1 (that is, in FIG. 1B). That is, in FIG. 1B, only the first right surface 6A that is arranged on the leftmost side in FIG. 2 is shown in FIG. 1B, and second to fifteenth right surfaces 6A are not shown in FIG. 1B.

Therefore, the fin 7A is able to collectively strengthen the refrigerant flow that approaches the cooled body 3 side (upper side in FIG. 1B) compared to a case where the plurality of right surfaces 6A are not formed to be overlapped with one another when seen in the first direction D1. As a result, it is possible to reduce a refrigerant flow that passes through the refrigerant flow passage 9 without cooling the cooled body 3 and improve a cooling efficiency of the cooled body 3.

As shown in FIG. 1B and FIG. 2, the fifteen left surfaces 6B of the fin 7A are formed to be overlapped with one another when seen in the first direction D1 (that is, in FIG. 1B). That is, in FIG. 1B, only the first left surface 6B that is arranged on the leftmost side in FIG. 2 is shown in FIG. 1B, and second to fifteenth left surfaces 6B are not shown in FIG. 1B.

Therefore, the fin 7A is able to collectively strengthen the refrigerant flow that is separated from the cooled body 3 (downward in FIG. 1B) compared to a case where the plurality of left surfaces 6B are not formed to be overlapped with one another when seen in the first direction D1. As a result, it is possible to reduce a refrigerant flow that passes through the refrigerant flow passage 9 without cooling the cooled body 3 and improve a cooling efficiency of the cooled body 3.

As shown in FIG. 1B, the fifteen left surfaces 6A of the fin 7B are formed to be overlapped with one another when seen in the first direction D1 (that is, in FIG. 1B).

That is, in FIG. 1B, only the first left surface 6A that is arranged on the front side is shown in FIG. 1B, and second to fifteenth left surfaces 6A are not shown in FIG. 1B. Therefore, the fin 7B is able to collectively strengthen the refrigerant flow that approaches the cooled body 3 side (upper side in FIG. 1B) compared to a case where the plurality of left surfaces 6A are not formed to be overlapped with one another when seen in the first direction D1.

As shown in FIG. 1B, the fifteen right surfaces 6B of the fin 7B are formed to be overlapped with one another when seen in the first direction D1 (that is, in FIG. 1B).

That is, in FIG. 1B, only the first right surface 6B that is arranged on the front side is shown in FIG. 1B, and second to fifteenth right surfaces 6B are not shown in FIG. 1B. Therefore, the fin 7B is able to collectively strengthen the refrigerant flow that is separated from the cooled body 3 (downward in FIG. 1B) compared to a case where the plurality of right surfaces 6B are not formed to be overlapped with one another when seen in the first direction D1.

As a result, it is possible to reduce a refrigerant flow that passes through the refrigerant flow passage 9 without cooling the cooled body 3 and improve a cooling efficiency of the cooled body 3.

In order to achieve a similar objective, as shown in FIG. 1B, the fifteen right surfaces 6A of the fin 7C are formed to be overlapped with one another when seen in the first direction D1 (that is, in FIG. 1B). The fifteen left surfaces 6B of the fin 7C are formed to be overlapped with one another when seen in the first direction D1 (that is, in FIG. 1B).

As shown in FIG. 1B, the fifteen left surfaces 6A of the fin 7D are formed to be overlapped with one another when seen in the first direction D1 (that is, in FIG. 1B). The fifteen right surfaces 6B of the fin 7D are formed to be overlapped with one another when seen in the first direction D1 (that is, in FIG. 1B).

As shown in FIG. 1B, the fifteen right surfaces 6A of the fin 7E are formed to be overlapped with one another when seen in the first direction D1 (that is, in FIG. 1B). The fifteen left surfaces 6B of the fin 7E are formed to be overlapped with one another when seen in the first direction D1 (that is, in FIG. 1B).

As shown in FIG. 1B, when seen in the first direction D1 (that is, in FIG. 1B), the right surface 6A of the fin 7A and the left surface 6A of the fin 7B are overlapped with each other, and the right surface 6A of the fin 7C and the left surface 6A of the fin 7D are overlapped with each other.

Therefore, it is possible to strengthen the refrigerant flow that approaches the cooled body 3 side (upper side in FIG. 1B), and it is possible to improve a cooling efficiency of the cooled body 3 compared to a case where when seen in the first direction D1, the right surface 6A of the fin 7A and the left surface 6A of the fin 7B are not overlapped with each other, and the right surface 6A of the fin 7C and the left surface 6A of the fin 7D are not overlapped with each other.

As shown in FIG. 1B, when seen in the first direction D1 (that is, in FIG. 1B), the right surface 6B of the fin 7B and the left surface 6B of the fin 7C are overlapped with each other, and the right surface 6B of the fin 7D and the left surface 6B of the fin 7E are overlapped with each other.

Therefore, by strengthening the refrigerant flow that is separated from the cooled body 3 (that is, moves downward in FIG. 1B), it is possible to prompt the movement of the refrigerant in the vertical direction (vertical direction in FIG. 1B) in the refrigerant flow passage 9 and to improve a cooling efficiency of the cooled body 3 compared to a case where when seen in the first direction D1, the right surface 6B of the fin 7B and the left surface 6B of the fin 7C are not overlapped with each other, and the right surface 6B of the fin 7D and the left surface 6B of the fin 7E are not overlapped with each other.

As described above, in the example shown in FIG. 1A to FIG. 4, the heat release part 6 includes the fins 7A, 7B, 7C, 7D, 7E. Therefore, compared to a case where the heat release part 6 includes only the fin 7A, it is possible to strengthen the refrigerant flow that crosses with the first direction D1, and it is possible to improve a cooling efficiency of the cooled body 3.

In the example shown in FIG. 1A to FIG. 4, a gradient θ1 of a center-side part in a height direction and a gradient θ2 of an outer-side part in the height direction of the fin 7A in each of cross-sections shown in FIGS. 3A to 3F are changed continuously in accordance with the position of the cross-section.

In detail, a gradient θ1 (an angle θ1 which a straight line L1 forms) of the center-side part in the height direction of the fin 7A in a B-B cross-section of FIG. 3B is slightly smaller than a gradient θ1 (an angle θ1 which a straight line L1 forms) of the center-side part in the height direction of the fin 7A in an A-A cross-section of FIG. 3A.

A gradient θ1 (an angle θ1 which a straight line L1 forms) of the center-side part in the height direction of the fin 7A in a C-C cross-section of FIG. 3C is smaller than the gradient θ1 (the angle θ1 which the straight line L1 forms) of the center-side part in the height direction of the fin 7A in the B-B cross-section of FIG. 3B. A gradient θ2 (an angle θ2 which a straight line L2 forms) of the outer-side part in the height direction of the fin 7A in the C-C cross-section of FIG. 3C is larger than the gradient θ1 (the angle θ1 which the straight line L1 forms) of the center-side part in the height direction of the fin 7A in the C-C cross-section of FIG. 3C.

In a D-D cross-section (cross-section that includes the central axis line (straight line L1) of the fin 7A) of FIG. 3D, the fin 7A extends in the vertical direction in FIG. 3D (straight line L2) and is orthogonal to the central axis line (straight line L1) of the fin 7A. A gradient θ1 (an angle θ1 (0°) which a straight line L1 forms) of the center-side part in the height direction of the fin 7A in the D-D cross-section of FIG. 3D is smaller than the gradient θ1 (the angle θ1 which the straight line L1 forms) of the center-side part in the height direction of the fin 7A in the C-C cross-section of FIG. 3C. A gradient θ2 (an angle θ2 (90°) which a straight line L2 forms) of the outer-side part in the height direction of the fin 7A in the D-D cross-section of FIG. 3D is smaller than the gradient θ2 (the angle θ2 which the straight line L2 forms) of the outer-side part in the height direction of the fin 7A in the C-C cross-section of FIG. 3C.

A gradient θ1 (an angle θ1 (obtuse angle) which a straight line L1 forms) of the center-side part in the height direction of the fin 7A in a E-E cross-section of FIG. 3E is larger than a gradient θ1 (an angle θ1 (obtuse angle) which a straight line L1 forms) of the center-side part in the height direction of the fin 7A in a F-F cross-section of FIG. 3F. A gradient θ2 (an angle θ2 (obtuse angle) which a straight line L2 forms) of the outer-side part in the height direction of the fin 7A in the E-E cross-section of FIG. 3E is smaller than the gradient θ1 (the angle θ1 (obtuse angle) which the straight line L1 forms) of the center-side part in the height direction of the fin 7A in the E-E cross-section of FIG. 3E.

A gradient θ1 (an angle θ1 (obtuse angle) which a straight line L1 forms) of the center-side part in the height direction of the fin 7A in a F-F cross-section of FIG. 3F is smaller than the gradient θ1 (the angle θ1 (obtuse angle) which the straight line L1 forms) of the center-side part in the height direction of the fin 7A in the E-E cross-section of FIG. 3E.

As described above, as proceeding to the A-A cross-section, the B-B cross-section, the C-C cross-section, and the D-D cross-section in this order, the gradient θ1 (the angle θ1 which the straight line L1 forms) of the center-side part in the height direction of the fin 7A is gradually decreased, and the gradient becomes 0 (θ1=0°) in the D-D cross-section. Then, as proceeding to the D-D cross-section, the E-E cross-section, and the F-F cross-section in this order, the gradient (the angle θ1 (obtuse angle) which the straight line L1 forms) of the center-side part in the height direction of the fin 7A is gradually decreased from the 180° side. That is, the angle (180°−θ1) in FIG. 3E and FIG. 3F is gradually increased as proceeding to the E-E cross-section and the F-F cross-section in this order.

As proceeding to the C-C cross-section and the D-D cross-section in this order, the gradient (the angle θ2 which the straight line L2 forms) of the outer-side part in the height direction of the fin 7A is gradually increased and is orthogonal (becomes θ2=90°) to the central axis line of the fin 7A in the D-D cross-section. Then, as proceeding to the D-D cross-section and the E-E cross-section in this order, the gradient (the angle θ2 which the straight line L2 forms) of the outer-side part in the height direction of the fin 7A is gradually increased beyond 90°.

In the example shown in FIG. 1A to FIG. 4, a trajectory of a cross-sectional shape obtained by the cross-sectional shape shown of the fin 7A shown in FIG. 3D being rotated around the central axis line of the fin 7A and being swept in the rightward direction in FIG. 3D corresponds to the outer shape of the fin 7A shown in FIG. 1A to FIG. 4.

### Second Embodiment

A second embodiment of a cooling apparatus 2 of the present invention is described.

The cooling apparatus 2 of the second embodiment has a configuration similar to the cooling apparatus 2 of the first embodiment described above except for the points described later. Accordingly, the cooling apparatus 2 of the second embodiment is able to provide an advantage similar to that of the cooling apparatus 2 of the first embodiment described above except for the points described later.

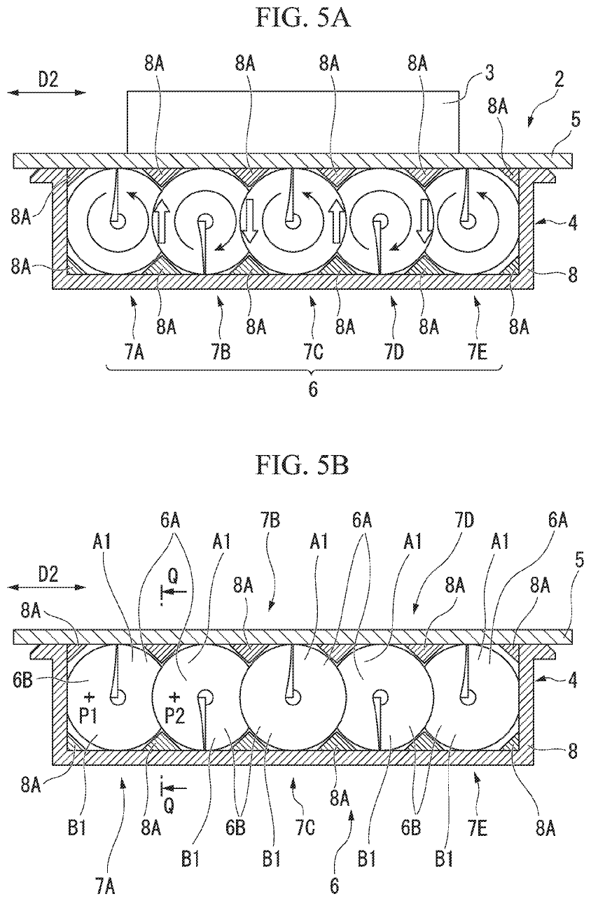

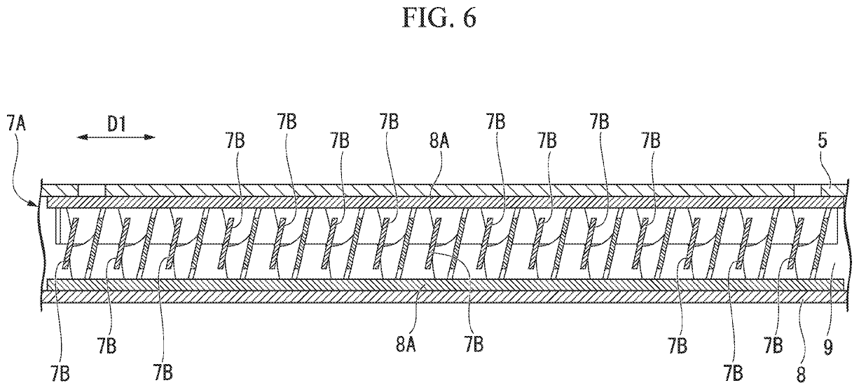

FIGS. 5A and 5B are views showing an example of the cooling apparatus 2 of the second embodiment. In detail, FIG. 5A is a view showing a relationship between a cooled body 3 and an internal structure of a cooling part 4 and the like of the cooling apparatus 2 of the second embodiment. FIG. 5B is a view extracting and showing only the cooling part 4 in FIG. 5A. FIG. 6 is a cross-sectional view of the cooling part 4 along a Q-Q line in FIG. 5B.

In the example shown in FIGS. 1A, 1B and FIG. 2, when seen in the first direction D1 (that is, in FIG. 1B), a part where the fins 7A, 7B, 7C, 7D, 7E are not present is present in the refrigerant flow passage 9. Therefore, in the example shown in FIGS. 1A, 1B and FIG. 2, a refrigerant that passes by the inside of the refrigerant flow passage 9 without hitting the fins 7A, 7B, 7C, 7D, 7E is present.

On the other hand, in the example shown in FIGS. 5A, 5B and FIG. 6, a rib 8A is arranged at a part where the fins 7A, 7B, 7C, 7D, 7E are not present when seen in the first direction D1 (that is, in FIG. 5B). As shown in FIG. 6, in the first direction D1 (right-to-left direction in FIG. 6), the rib 8A extends throughout a range where the fins 7A, 7B, 7C, 7D, 7E are present.

Therefore, in the example shown in FIGS. 5A, 5B and FIG. 6, it is possible to reduce a refrigerant flow that passes through the refrigerant flow passage 9 without cooling the fins 7A, 7B, 7C, 7D, 7E, and it is possible to improve a cooling efficiency of the cooled body 3.

### Third Embodiment

A third embodiment of a cooling apparatus 2 of the present invention is described.

The cooling apparatus 2 of the third embodiment has a configuration similar to the cooling apparatus 2 of the first embodiment described above except for the points described later. Accordingly, the cooling apparatus 2 of the third embodiment is able to provide an advantage similar to that of the cooling apparatus 2 of the first embodiment described above except for the points described later.

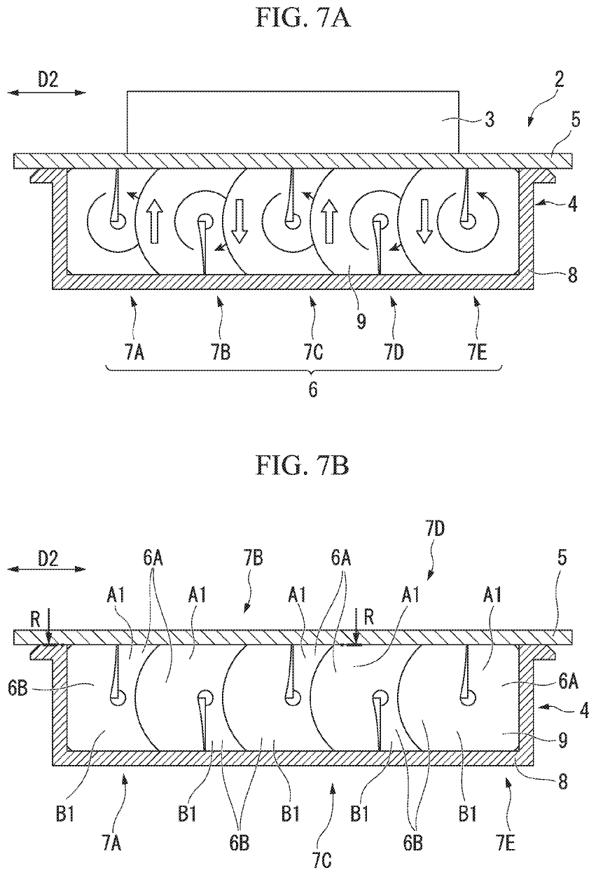

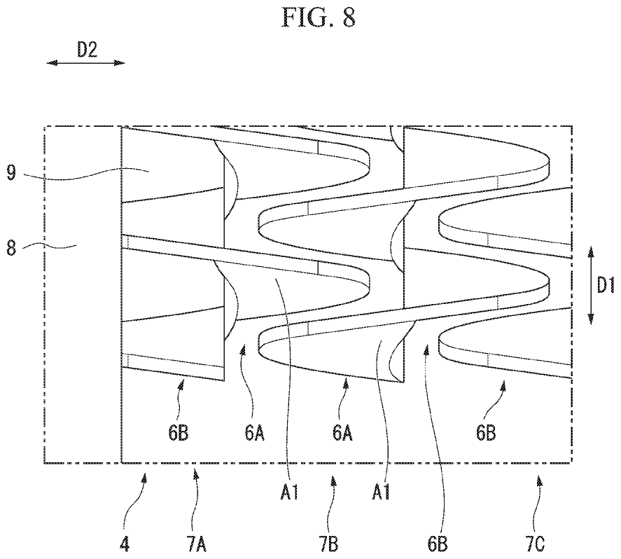

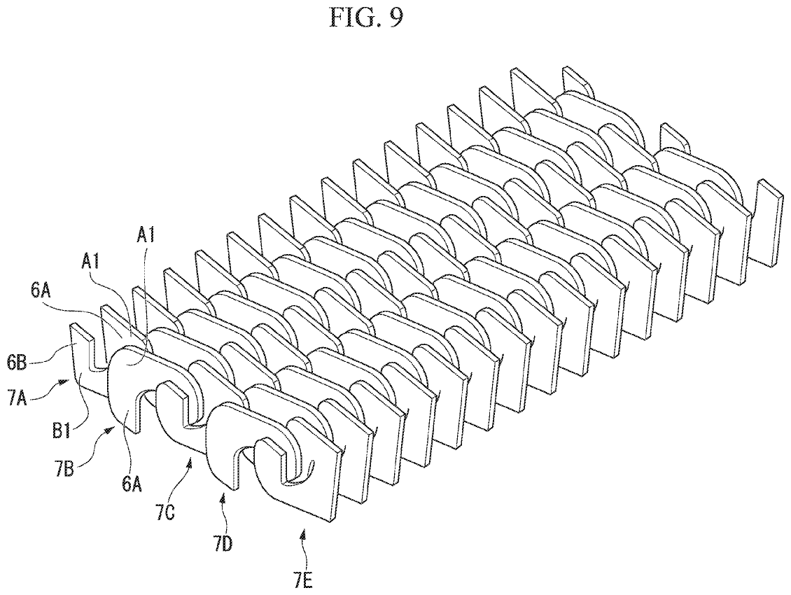

FIGS. 7A and 7B are views showing an example of the cooling apparatus 2 of the third embodiment. In detail, FIG. 7A is a view showing a relationship between a cooled body 3 and an internal structure of a cooling part 4 and the like of the cooling apparatus 2 of the third embodiment. FIG. 7B is a view extracting and showing only the cooling part 4 in FIG. 7A. FIG. 8 is a partial cross-sectional view of the cooling part 4 along a R-R line in FIG. 7B. FIG. 9 is a perspective view of the fins 7A, 7B, 7C, 7D, 7E of the cooling apparatus 2 of the third embodiment.

In the example shown in FIGS. 1A, 1B and FIG. 2, when seen in the first direction D1 (that is, in FIG. 1B), the outer shape (profile) of each of the fins 7A, 7B, 7C, 7D, 7E is a round shape. Therefore, in the example shown in FIGS. 1A, 1B and FIG. 2, a gap (a part where the fins 7A, 7B, 7C, 7D, 7E are not present) is present between the profile of each of the fins 7A, 7B, 7C, 7D, 7E and a lower surface of a mount part 5 or an inner surface of a case part 8, and a refrigerant that passes by the inside of the refrigerant flow passage 9 without hitting the fins 7A, 7B, 7C, 7D, 7E is present.

On the other hand, in the example shown in FIG. 7A to FIG. 9, when seen in the first direction D1 (that is, in FIG. 7B), the outer shape (profile) of the fins 7A, 7B, 7C, 7D, 7E is matched with the cross-sectional shape of the refrigerant flow passage 9.

In the example shown in FIG. 7A to FIG. 9, the diameter of a round shape part of the fins 7A, 7B, 7C, 7D, 7E in FIG. 7B is larger than a size in the vertical direction (vertical direction in FIG. 7B) of the refrigerant flow passage 9.

On the other hand, when the diameter of the round shape part of the fins 7A, 7B, 7C, 7D, 7E is larger than the size in the vertical direction (vertical direction in FIG. 7B) of the refrigerant flow passage 9, part of the fins 7A, 7B, 7C, 7D, 7E protrudes from the refrigerant flow passage 9.

Therefore, in the example shown in FIG. 7A to FIG. 9, the part of the fins 7A, 7B, 7C, 7D, 7E that protrudes from the refrigerant flow passage 9 is cut.

As a result, in the example shown in FIG. 7A to FIG. 9, as described above, when seen in the first direction D1 (that is, in FIG. 7B), the outer shape (profile) of the fins 7A, 7B, 7C, 7D, 7E is matched with the cross-sectional shape of the refrigerant flow passage 9.

Therefore, in the example shown in FIG. 7A to FIG. 9, it is possible to reduce the refrigerant that passes by the inside of the refrigerant flow passage 9 without hitting the fins 7A, 7B, 7C, 7D, 7E.

As shown in FIG. 8, also in the cooling apparatus 2 of the third embodiment, similarly to the cooling apparatus 2 of the first embodiment, the right surface 6A of the fin 7A and the left surface 6A of the fin 7B are overlapped with each other.

### Fourth Embodiment

A fourth embodiment of a cooling apparatus 2 of the present invention is described.

The cooling apparatus 2 of the fourth embodiment has a configuration similar to the cooling apparatus 2 of the third embodiment described above except for the points described later. Accordingly, the cooling apparatus 2 of the fourth embodiment is able to provide an advantage similar to that of the cooling apparatus 2 of the third embodiment described above except for the points described later.

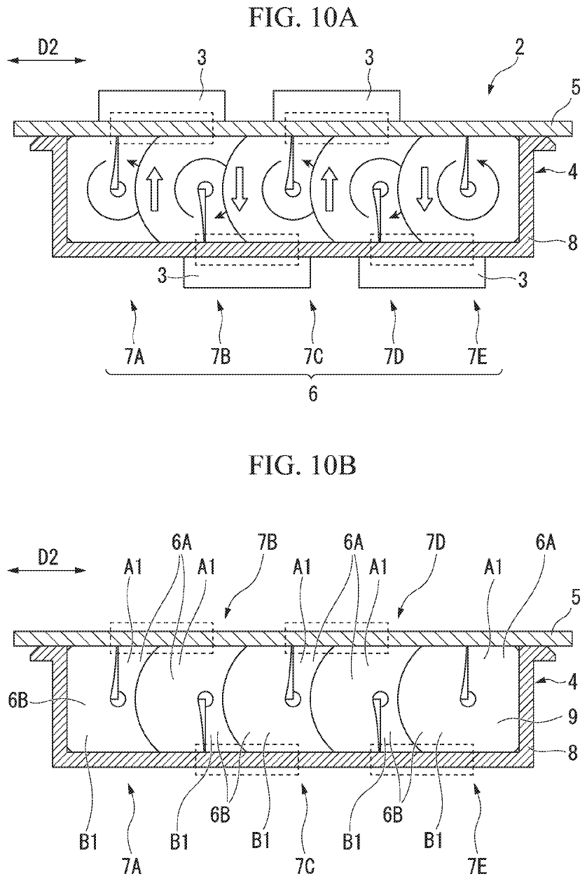

FIGS. 10A and 10B are views showing an example of the cooling apparatus 2 of the fourth embodiment. In detail, FIG. 10A is a view showing a relationship between a cooled body 3 and an internal structure of a cooling part 4 and the like of the cooling apparatus 2 of the fourth embodiment.

FIG. 10B is a view extracting and showing only the cooling part 4 in FIG. 10A.

In the example shown in FIG. 7A, the cooling apparatus 2 includes one cooled body 3. The cooling part 4 includes one mount part 5. The one cooled body 3 described above is mounted on one (upper side in FIG. 7A) surface of the mount part 5.

On the other hand, in the example shown in FIG. 10A, the cooling apparatus 2 includes a plurality of (for example, four) cooled bodies 3. The cooling part 4 includes two mount parts 5. Two of the four cooled bodies 3 described above are mounted on one (upper side in FIG. 10A) surface of the upper (upper side in FIG. 10A) mount part 5. The other two of the four cooled bodies 3 described above are mounted on one (lower side in FIG. 10A) surface of the lower (lower side in FIG. 10A) mount part 5.

In the example shown in FIG. 10A and FIG. 10B, a left upper (left upper in FIG. 10A) cooled body 3 is arranged at a part where the right surface 6A of the fin 7A and the left surface 6A of the fin 7B are arranged in the second direction D2 (right-to-left direction in FIG. 10A and FIG. 10B).

Therefore, the refrigerant flow in the upward direction (upward direction in FIG. 10A and FIG. 10B) that is formed by the right surface 6A of the fin 7A and the left surface 6A of the fin 7B hits a portion of the upper (upper in FIG. 10A and FIG. 10B) mount part 5 where the left upper cooled body 3 is mounted.

As a result, the refrigerant flow that hits the portion where the left upper cooled body 3 is mounted makes it possible to improve a cooling efficiency of the left upper cooled body 3.

In the example shown in FIG. 10A and FIG. 10B, a right upper (right upper in FIG. 10A) cooled body 3 is arranged at a part where the right surface 6A of the fin 7C and the left surface 6A of the fin 7D are arranged in the second direction D2 (right-to-left direction in FIG. 10A and FIG. 10B).

Therefore, the refrigerant flow in the upward direction (upward direction in FIG. 10A and FIG. 10B) that is formed by the right surface 6A of the fin 7C and the left surface 6A of the fin 7D hits a portion of the upper (upper in FIG. 10A and FIG. 10B) mount part 5 where the right upper cooled body 3 is mounted.

As a result, the refrigerant flow that hits the portion where the right upper cooled body 3 is mounted makes it possible to improve a cooling efficiency of the right upper cooled body 3.

In the example shown in FIG. 10A and FIG. 10B, a left lower (left lower in FIG. 10A) cooled body 3 is arranged at a part where the right surface 6B of the fin 7B and the left surface 6B of the fin 7C are arranged in the second direction D2 (right-to-left direction in FIG. 10A and FIG. 10B).

Therefore, the refrigerant flow in the downward direction (downward direction in FIG. 10A and FIG. 10B) that is formed by the right surface 6B of the fin 7B and the left surface 6B of the fin 7C hits a portion of the lower (lower in FIG. 10A and FIG. 10B) mount part 5 where the left lower cooled body 3 is mounted.

As a result, the refrigerant flow that hits the portion where the left lower cooled body 3 is mounted makes it possible to improve a cooling efficiency of the left lower cooled body 3.

In the example shown in FIG. 10A and FIG. 10B, a right lower (right lower in FIG. 10A) cooled body 3 is arranged at a part where the right surface 6B of the fin 7D and the left surface 6B of the fin 7E are arranged in the second direction D2 (right-to-left direction in FIG. 10A and FIG. 10B).

Therefore, the refrigerant flow in the downward direction (downward direction in FIG. 10A and FIG. 10B) that is formed by the right surface 6B of the fin 7D and the left surface 6B of the fin 7E hits a portion of the lower (lower in FIG. 10A and FIG. 10B) mount part 5 where the right lower cooled body 3 is mounted.

As a result, the refrigerant flow that hits the portion where the right lower cooled body 3 is mounted makes it possible to improve a cooling efficiency of the right lower cooled body 3.

### Fifth Embodiment

A cooling apparatus 2 of a fifth embodiment is formed by appropriately combining the cooling apparatuses 2 of the first to fourth embodiments described above.

### Application Example

An application example of the cooling apparatus 2 of the present invention is described with reference to the drawings.

FIG. 11 is a view showing an example of a part of a vehicle 10 to which the cooling apparatuses 2 of the first to fifth embodiments are applicable.

In the example shown in FIG. 11, any one of the cooling apparatuses 2 of the first to fifth embodiments, or a combination of some of the cooling apparatuses 2 of the first to fifth embodiments is applied to the vehicle 10.

That is, by using any one of the cooling apparatuses 2 of the first to fifth embodiments, or by a combination of some of the cooling apparatuses 2 of the first to fifth embodiments, switching elements UH, UL, VH, VL, WH, WL of a first electric power conversion circuit part 31, switching elements UH, UL, VH, VL, WH, WL of a second electric power conversion circuit part 32, and switching elements S1, S2 of a third electric power conversion circuit part 33 as the cooled body 3 are cooled.

In the example shown in FIG. 11, the vehicle 10 includes a battery 11 (BATT), a first motor 12 (MOT) for travel drive, and a second motor 13 (GEN) for electric power generation in addition to an electric power conversion apparatus 1.

The battery 11 includes a battery case and a plurality of battery modules that are accommodated inside the battery case. The battery module includes a plurality of battery cells that are connected together in series. The battery 11 includes a positive terminal PB and a negative terminal NB that are connected to a DC connector 1a of the electric power conversion apparatus 1. Each of the positive terminal PB and the negative terminal NB is connected to each of a positive terminal end and a negative terminal end of the plurality of battery modules that are connected together in series inside the battery case.

The first motor 12 generates a rotation drive force (power running operation) by electric power that is supplied from the battery 11. The second motor 13 generates electric power by a rotation drive force that is input to a rotation shaft. The second motor 13 has a configuration in which a rotation power of an internal combustion engine is transmittable to the second motor 13. For example, each of the first motor 12 and the second motor 13 is a brushless DC motor of a three-phase AC. The three-phase consists of a U-phase, a V-phase, and a W-phase. Each of the first motor 12 and the second motor 13 is an inner rotor type. Each of the first motor 12 and the second motor 13 includes a rotator having a field-permanent magnet and a stator having a three-phase stator winding wire for generating a rotation magnetic field that allows the rotator to be rotated. The three-phase stator winding wire of the first motor 12 is connected to a first three-phase connector 1b of the electric power conversion apparatus 1. The three-phase stator winding wire of the second motor 13 is connected to a second three-phase connector 1c of the electric power conversion apparatus 1.

The electric power conversion apparatus 1 shown in FIG. 11 includes a power module 21, a reactor 22, a condenser unit 23, a resistor 24, a first current sensor 25, a second current sensor 26, a third current sensor 27, an electronic control unit 28 (MOT GEN ECU), and a gate drive unit 29 (G/D VCU ECU).

The power module 21 includes the first electric power conversion circuit part 31, the second electric power conversion circuit part 32, and the third electric power conversion circuit part 33.

In the example shown in FIG. 11, output-side conductive bodies 51 of the first electric power conversion circuit part 31 are integrated and connected to a first three-phase connector 1b. That is, the output-side conductive body 51 of the first electric power conversion circuit part 31 is connected to a three-phase stator winding wire of the first motor 12 via the first three-phase connector 1b.

Positive-side conductive bodies PI of the first electric power conversion circuit part 31 are integrated and connected to the positive terminal PB of the battery 11.

Negative-side conductive bodies NI of the first electric power conversion circuit part 31 are integrated and connected to the negative terminal NB of the battery 11.

That is, the first electric power conversion circuit part 31 converts a DC electric power that is input from the battery 11 via the third electric power conversion circuit part 33 into a three-phase AC electric power.

In the example shown in FIG. 11, output-side conductive bodies 52 of the second electric power conversion circuit part 32 are integrated and connected to a second three-phase connector 1c. That is, the output-side conductive body 52 of the second electric power conversion circuit part 32 is connected to a three-phase stator winding wire of the second motor 13 via the second three-phase connector 1c.

Positive-side conductive bodies PI of the second electric power conversion circuit part 32 are integrated and connected to the positive terminal PB of the battery 11 and the positive-side conductive body PI of the first electric power conversion circuit part 31.

Negative-side conductive bodies NI of the second electric power conversion circuit part 32 are integrated and connected to the negative terminal NB of the battery 11 and the negative-side conductive body NI of the first electric power conversion circuit part 31.

The second electric power conversion circuit part 32 converts a three-phase AC electric power that is input from the second motor 13 into a DC electric power. The DC electric power that is converted by the second electric power conversion circuit part 32 can be supplied to at least one of the battery 11 and the first electric power conversion circuit part 31.

In the example shown in FIG. 11, a U-phase-switching element UH, a V-phase-switching element VH, and a W-phase-switching element WH of the first electric power conversion circuit part 31 and a U-phase-switching element UH, a V-phase-switching element VH, and a W-phase-switching element WH of the second electric power conversion circuit part 32 are connected to a positive bus bar PI. The positive bus bar PI is connected to a positive bus bar 50p of the condenser unit 23.

A U-phase-switching element UL, a V-phase-switching element VL, and a W-phase-switching element WL of the first electric power conversion circuit part 31 and a U-phase-switching element UL, a V-phase-switching element VL, and a W-phase-switching element WL of the second electric power conversion circuit part 32 are connected to a negative bus bar NI. The negative bus bar NI is connected to a negative bus bar 50n of the condenser unit 23.

In the example shown in FIG. 11, the first bus bar 51 of the first electric power conversion circuit part 31 is connected to a first input/output terminal Q1. The first input/output terminal Q1 is connected to the first three-phase connector 1b. A connection point TI of phases of the first electric power conversion circuit part 31 is connected to the stator winding wire of each phase of the first motor 12 via the first bus bar 51, the first input/output terminal Q1, and the first three-phase connector 1b.

The second bus bar 52 of the second electric power conversion circuit part 32 is connected to a second input/output terminal Q2. The second input/output terminal Q2 is connected to the second three-phase connector 1c. A connection point TI of phases of the second electric power conversion circuit part 32 is connected to the stator winding wire of each phase of the second motor 13 via the second bus bar 52, the second input/output terminal Q2, and the second three-phase connector 1c.

In the example shown in FIG. 11, the U-phase-switching elements UH, UL, the V-phase-switching elements VH, VL, and the W-phase-switching elements WH, WL of the first electric power conversion circuit part 31 include a flywheel diode.

Similarly, the U-phase-switching elements UH, UL, the V-phase-switching elements VH, VL, and the W-phase-switching elements WH, WL of the second electric power conversion circuit part 32 include a flywheel diode.

In the example shown in FIG. 11, the gate drive unit 29 inputs a gate signal to the U-phase-switching elements UH, UL, the V-phase-switching elements VH, VL, and the W-phase-switching elements WH, WL of the first electric power conversion circuit part 31.

Similarly, the gate drive unit 29 inputs a gate signal to the U-phase-switching elements UH, UL, the V-phase-switching elements VH, VL, and the W-phase-switching elements WH, WL of the second electric power conversion circuit part 32.

The first electric power conversion circuit part 31 converts DC electric power that is input via the third electric power conversion circuit part 33 from the battery 11 into three-phase AC electric power and supplies AC U-phase, V-phase, and W-phase currents to the three-phase stator winding wire of the first motor 12. The second electric power conversion circuit part 32 converts the three-phase AC electric power that is output from the three-phase stator winding wire of the second motor 13 into DC electric power by the ON (conduction)/OFF (disconnection) drive of the U-phase-switching elements UH, UL, the V-phase-switching elements VH, VL, and the W-phase-switching elements WH, WL of the second electric power conversion circuit part 32 that are synchronized with the rotation of the second motor 13.

The third electric power conversion circuit part 33 is a voltage control unit (VCU). The third electric power conversion circuit part 33 includes switching elements S1, S2 of one phase.

A positive-side electrode of the switching element S1 is connected to a positive bus bar PV. The positive bus bar PV is connected to the positive bus bar 50p of the condenser unit 23. A negative-side electrode of the switching element S2 is connected to a negative bus bar NV. The negative bus bar NV is connected to the negative bus bar 50n of the condenser unit 23. The negative bus bar 50n of the condenser unit 23 is connected to the negative terminal NB of the battery 11. A negative-side electrode of the switching element S1 is connected to a positive-side electrode of the switching element S2. The switching element S1 and the switching element S2 include a flywheel diode.

A third bus bar 53 that constitutes a connection point of the switching element S1 and the switching element S2 of the third electric power conversion circuit part 33 is connected to one end of the reactor 22. The other end of the reactor 22 is connected to the positive terminal PB of the battery 11. The reactor 22 includes a coil and a temperature sensor that detects a temperature of the coil. The temperature sensor is connected to the electronic control unit 28 by a signal line.

The third electric power conversion circuit part 33 switches between ON (conduction) and OFF (disconnection) of the switching element S1 and the switching element S2 on the basis of a gate signal that is input to a gate electrode of the switching element S1 and a gate electrode of the switching element S2 from the gate drive unit 29.

At the time of increasing the voltage, the third electric power conversion circuit part 33 alternately switches between a first state in which the switching element S2 is set to ON (conduction) and the switching element S1 is set to OFF (disconnection), and a second state in which the switching element S2 is set to OFF (disconnection) and the switching element S1 is set to ON (conduction). In the first state, a current flows sequentially through the positive terminal PB of the battery 11, the reactor 22, the switching element S2, and the negative terminal NB of the battery 11, and the reactor 22 is excited by DC excitation and accumulates a magnetic energy. In the second state, a voltage (induction voltage) is generated between both ends of the reactor 22 so as to prevent a change in a magnetic flux arising from the current that flows through the reactor 22 being disconnected. The induction voltage caused by the magnetic energy accumulated in the reactor 22 is superimposed on the battery voltage, and an increased voltage that is higher than an inter-terminal voltage of the battery 11 is applied between the positive bus bar PV and the negative bus bar NV of the third electric power conversion circuit part 33.

At the time of regeneration, the third electric power conversion circuit part 33 alternately switches between the second state and the first state. In the second state, a current flows sequentially through the positive bus bar PV of the third electric power conversion circuit part 33, the switching element S1, the reactor 22, and the positive terminal PB of the battery 11, and the reactor 22 is excited by DC excitation and accumulates a magnetic energy. In the first state, a voltage (induction voltage) is generated between both ends of the reactor 22 so as to prevent a change in a magnetic flux arising from the current that flows through the reactor 22 being disconnected. The induction voltage caused by the magnetic energy accumulated in the reactor 22 is decreased, and a decreased voltage that is lower than a voltage between the positive bus bar PV and the negative bus bar NV of the third electric power conversion circuit part 33 is applied between the positive terminal PB and the negative terminal NB of the battery 11.

The condenser unit 23 includes a first smoothing capacitor 41, a second smoothing capacitor 42, and a noise filter 43.

The first smoothing capacitor 41 is connected to and between the positive terminal PB and the negative terminal NB of the battery 11. The first smoothing capacitor 41 smooths a voltage variation that arises in accordance with an ON/OFF switching operation of the switching element S1 and the switching element S2 at the time of regeneration of the third electric power conversion circuit part 33.

The second smoothing capacitor 42 is connected to and between the positive bus bar PI and the negative bus bar NI of each of the first electric power conversion circuit part 31 and the second electric power conversion circuit part 32 and is connected to and between the positive bus bar PV and the negative bus bar NV of the third electric power conversion circuit part 33. The second smoothing capacitor 42 is connected to a plurality of positive bus bars PI, a plurality of negative bus bars NI, the positive bus bar PV, and the negative bus bar NV via the positive bus bar 50p and the negative bus bar 50n. The second smoothing capacitor 42 smooths a voltage variation that arises in accordance with an ON/OFF switching operation of the U-phase-switching elements UH, UL, the V-phase-switching elements VH, VL, and the W-phase-switching elements WH, WL of the first electric power conversion circuit part 31 and the second electric power conversion circuit part 32. The second smoothing capacitor 42 smooths a voltage variation that arises in accordance with an ON/OFF switching operation of the switching element S1 and the switching element S2 at the time of increasing the voltage of the third electric power conversion circuit part 33.

The noise filter 43 is connected to and between the positive bus bar PI and the negative bus bar NI of each of the first electric power conversion circuit part 31 and the second electric power conversion circuit part 32 and is connected to and between the positive bus bar PV and the negative bus bar NV of the third electric power conversion circuit part 33. The noise filter 43 includes two capacitors that are connected to each other in series. A connection point of the two capacitors is connected to a body ground of the vehicle 10 or the like.

The resistor 24 is connected to and between the positive bus bar PI and the negative bus bar NI of each of the first electric power conversion circuit part 31 and the second electric power conversion circuit part 32 and is connected to and between the positive bus bar PV and the negative bus bar NV of the third electric power conversion circuit part 33.

The first current sensor 25 is arranged on the first bus bar 51 that forms the connection point TI of phases of the first electric power conversion circuit part 31 and that is connected to the first input/output terminal Q1 and detects a current of each of the U-phase, the V-phase, and the W-phase. The second current sensor 26 is arranged on the second bus bar 52 that forms the connection point TI of phases of the second electric power conversion circuit part 32 and that is connected to the second input/output terminal Q2 and detects a current of each of the U-phase, the V-phase, and the W-phase. The third current sensor 27 is arranged on the third bus bar 53 that forms a connection point of the first transistor S1 and the second transistor S2 and that is connected to the reactor 22 and detects a current that flows through the reactor 22.

Each of the first current sensor 25, the second current sensor 26, and the third current sensor 27 is connected to the electronic control unit 28 via a signal line.

The electronic control unit 28 controls an operation of each of the first motor 12 and the second motor 13. For example, the electronic control unit 28 is a software function unit that functions by executing a predetermined program by a processor such as a CPU (Central Processing Unit). The software function unit is an ECU (Electronic Control Unit) that includes a processor such as the CPU, a ROM (Read-Only Memory) that stores a program, a RAM (Random-Access Memory) that temporarily stores data, and electronic circuitry such as a timer. At least part of the electronic control unit 28 may be an integrated circuit such as an LSI (Large-Scale Integration). For example, the electronic control unit 28 performs a current feedback control and the like using a current detection value of the first current sensor 25 and a current target value associated with a torque command value with respect to the first motor 12 and generates a control signal that is input to the gate drive unit 29. For example, the electronic control unit 28 performs a current feedback control and the like using a current detection value of the second current sensor 26 and a current target value associated with a regeneration command value with respect to the second motor 13 and generates a control signal that is input to the gate drive unit 29. The control signal is a signal indicating a timing at which an ON (conduction)/OFF (disconnection) drive of the U-phase-switching elements UH, UL, the V-phase-switching elements VH, VL, and the W-phase-switching elements WH, WL of the first electric power conversion circuit part 31 and the second electric power conversion circuit part 32 is performed. For example, the control signal is a pulse-width-modulated signal or the like.

The gate drive unit 29 generates a gate signal for performing an ON (conduction)/OFF (disconnection) drive of the U-phase-switching elements UH, UL, the V-phase-switching elements VH, VL, and the W-phase-switching elements WH, WL of the first electric power conversion circuit part 31 and the second electric power conversion circuit part 32 on the basis of the control signal that is received from the electronic control unit 28. For example, the gate drive unit 29 performs amplification, level shift, and the like of the control signal and generates the gate signal.

The gate drive unit 29 generates a gate signal for performing an ON (conduction)/OFF (disconnection) drive of each of the switching element S1 and the switching element S2 of the third electric power conversion circuit part 33. For example, the gate drive unit 29 generates a gate signal having a duty ratio associated with a voltage increase command at the time of increasing the voltage of the third electric power conversion circuit part 33 or a voltage decrease command at the time of regeneration of the third electric power conversion circuit part 33. The duty ratio is a ratio of the switching element S1 and the switching element S2.

In the example shown in FIG. 11, the cooling apparatuses 2 of the first to fifth embodiments are applied to the vehicle 10. However, in another example, the cooling apparatuses 2 of the first to fifth embodiments may be applied to other applications than the vehicle 10 such as, for example, an elevator, a pump, a fan, a rail vehicle, an air conditioner, a refrigerator, or a washer.

The embodiments of the present invention are described as an example, and the invention is not limited to the embodiments. The embodiments can be implemented as a variety of other embodiments, and a variety of omissions, replacements, and changes can be made without departing from the scope of the invention. The embodiments and modifications of the embodiments are included in the scope of the invention and also included in the invention described in the claims and equivalents thereof.

What is claimed is:

1. A cooling apparatus in which a refrigerant flows in a refrigerant flow passage and thereby cools a cooled body that is mounted on a mount part, the cooling apparatus comprising
a heat release part that is arranged in the refrigerant flow passage,
wherein the heat release part comprises
a plurality of first surfaces that are formed so as to approach the mount part side as proceeding in a first direction along a flow direction of the refrigerant flow passage and
a plurality of second surfaces that are formed so as to be separated from the mount part as proceeding in the first direction, and
the plurality of first surfaces and the plurality of second surfaces are alternately arranged in the first direction.

2. The cooling apparatus according to claim 1,
wherein the first surface includes a first part that is formed so as to approach one side in a second direction that is orthogonal to the first direction and that is parallel to the mount part as proceeding in the first direction, and
the second surface includes a second part that is formed so as to approach another side in the second direction as proceeding in the first direction.

3. The cooling apparatus according to claim 2,
wherein the first surface and the second surface are formed so as to be displaced from each other in the second direction when seen in the first direction.

4. The cooling apparatus according to claim 1,
wherein the plurality of first surfaces are formed to be overlapped with one another when seen in the first direction, and
the plurality of second surfaces are formed to be overlapped with one another when seen in the first direction.

5. The cooling apparatus according to claim 2,
wherein the plurality of first surfaces are formed to be overlapped with one another when seen in the first direction, and
the plurality of second surfaces are formed to be overlapped with one another when seen in the first direction.

6. The cooling apparatus according to claim 3,
wherein the plurality of first surfaces are formed to be overlapped with one another when seen in the first direction, and
the plurality of second surfaces are formed to be overlapped with one another when seen in the first direction.

7. The cooling apparatus according to claim 2,
wherein the heat release part includes at least
a first fin that extends in the first direction and
a second fin that is arranged adjacent to the first fin in the second direction and that extends in the first direction,
each of the first fin and the second fin comprises the first surface having the first part and the second surface having the second part,
one of the first fin and the second fin forms a refrigerant flow that swirls clockwise as proceeding in the first direction when seen in the first direction, and
the other of the first fin and the second fin forms a refrigerant flow that swirls counterclockwise as proceeding in the first direction when seen in the first direction.

8. The cooling apparatus according to claim 7,
wherein when seen in the first direction, the first surface of the first fin and the first surface of the second fin are overlapped with each other, or the second surface of the first fin and the second surface of the second fin are overlapped with each other.

9. The cooling apparatus according to claim 2,
wherein the cooled body is arranged at a position where the first surface is arranged in the second direction.
